(19) United States
(12) Patent Application Publication
(10) Pub. No.: US 2010/0067187 A1
(43) Pub. Date: Mar. 18, 2010

(54) MOTHERBOARD

(75) Inventor: Ting-Kuo Kao, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTeK COMPUTER INC., Taipei (TW)

(21) Appl. No.: 12/489,444

(22) Filed: Jun. 23, 2009

(30) Foreign Application Priority Data
Sep. 17, 2008 (TW) 97135698

(51) Int. Cl. H05K 7/00

(52) U.S. Cl. 361/679.32

(57) ABSTRACT

A motherboard is provided. The motherboard includes a chipset, a memory module slot, a bridge device, a plurality of first conducting wires and a plurality of second conducting wires. The first conducting wires are coupled between the chipset and the bridge device. The second conducting wires are coupled between the memory module slot and the bridge device. When the bridge device provides a Nth route set, the motherboard supports a Nth standard memory module inserted the memory module slot. The Nth route set is electrical connected between a Nth wire group of the first conducting wires and a Nth wire group of the second conducting wires, wherein N is a natural number. Further, transmission quality of signals is increased.

### CROSS-REFERENCE TO RELATED APPLICATION

This application claims the priority benefit of Taiwan application serial no. 97135698, filed on Sep. 17, 2008. The entirety of the above-mentioned patent application is hereby incorporated by reference herein and made a part of specification.

### BACKGROUND OF THE INVENTION

1. Field of the Invention

The present invention relates to a motherboard. More particularly, the present invention relates to a motherboard that can support memory modules of different standards.

2. Description of Related Art

A current personal computer system is mainly formed by a motherboard, interface cards and peripheral devices, wherein the motherboard can be regarded as a heart of the computer system. On the motherboard, besides a central processing unit (CPU), a chipset and slots for accommodating the interface cards, there also has a plurality of memory module slots for accommodating memory modules.

Generally, the memory module slot has a proof thinking device to prevent inserting of an incompatible memory module. Namely, each of the memory module slots can only support the memory module of a specific standard. In the conventional technique, to support more than two types of the memory module, the memory module slots of different standards have to be set on the motherboard, which is described in detail below with reference of a figure.

FIG. 1 is a schematic diagram illustrating a conventional motherboard. Referring to FIG. 1, on the motherboard 10, only a north bridge chip 20, a double-data-rate two (DDR2) memory module slot 31, a double-data-rate three (DDR3) memory module slot 32 and conducting wires 41-46, 51-56 are illustrated.

The conducting wires 41-46 are used for correspondingly connecting pins of the DDR2 memory module slot 31 to the pins of the north bridge chip 20. It should be noted that though a number of the pins of the DDR2 memory module slot 31 is the same to a number of the pins of the DDR3 memory module slot 32, the pins of the DDR2 memory module slot 31 cannot correspond to the pins of the DDR3 memory module slot 32 one by one. Therefore, in the conventional technique, the pins of the DDR2 memory module slot 31 have to be correspondingly connected to the pins of the DDR3 memory module slot 32 via the conducting wires 51-56. By such means, the motherboard 10 can support the DDR2 memory module or the DDR3 memory module. However, the conventional technique has a following disadvantage. In the conventional technique, the motherboard 10 cannot simultaneously support the memory module with the DDR2 standard and the memory module with the DDR3 standard. Namely, when the memory module with the DDR2 standard is inserted into the DDR2 memory module slot 31, the DDR3 memory module slot 32 is then in an idle state, which leads to a waste of the cost.

### SUMMARY OF THE INVENTION

The present invention is directed to a motherboard, which can support memory modules of different standards, and can also improve a signal transmission quality.

The present invention provides a motherboard including a chipset, a memory module slot, a bridge device, a plurality of first conducting wires and a plurality of second conducting wires. The first conducting wires are coupled between the chipset and the bridge device. The second conducting wires are coupled between the memory module slot and the bridge device. When the bridge device provides a first route set, the motherboard supports a first standard memory module inserted in the memory module slot. The first route set is electrical connected between a first wire group of the first conducting wires and a first wire group of the second conducting wires. When the bridge device provides a second route set, the motherboard supports a second standard memory module inserted in the memory module slot. The second route set is electrical connected between a second wire group of the first conducting wires and a second wire group of the second conducting wires.

In an embodiment of the present invention, the bridge device includes a slot. The slot is coupled to the first conducting wires and the second conducting wires, and is used for accommodating a wiring board. The wiring board has a first route set, a second route set or a combination thereof. In another embodiment, the wiring board is a printed circuit board.

In an embodiment of the present invention, the bridge device includes a connection switch. The connection switch is coupled to the first conducting wires and the second conducting wires, and has a first route set and a second route set. When the connection switch is switched to a first state, the first route set is electrical connected between a first wire group of the first conducting wires and a first wire group of the second conducting wires. When the connection switch is switched to a second state, the second route set is electrical connected between a second wire group of the first conducting wires and a second wire group of the second conducting wires.

In an embodiment of the present invention, the chipset includes a north bridge chip. In another embodiment, the first standard memory module can be a DDR2 memory module, and the second standard memory module can be a DDR3 memory module.

In the motherboard of the present invention, a plurality of the first conducting wires is coupled between the chipset and the bridge device, and a plurality of the second conducting wires is coupled between the memory module slot and the bridge device. When the bridge device provides a N^{th} route set, the motherboard supports a N^{th} standard memory module inserted in the memory module slot. The N^{th} route set is electrical connected between a N^{th} wire group of the first conducting wires and a N^{th} wire group of the second conducting wires, wherein N is a natural number. By such means, not only the motherboard can support memory modules of different standards, but also the signal transmission quality is improved.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a conventional motherboard.

FIG. 2 is a schematic diagram illustrating a motherboard according to a first embodiment of the present invention.

FIG. 3 is a schematic diagram illustrating a bridge device according to a first embodiment of the present invention.

FIG. 4 is a top view of a slot according to a first embodiment of the present invention.

FIG. 5 is a three-dimensional view of a PCB and a slot according to a first embodiment of the present invention.

FIG. 6 is three-dimensional view of another PCB and a slot according to a first embodiment of the present invention.

FIG. 7 is a schematic diagram illustrating a PCB according to a second embodiment of the present invention.

FIG. 8 is a top view of a slot according to a third embodiment of the present invention.

FIG. 9 is a three-dimensional view of a PCB and a slot according to a third embodiment of the present invention.

FIG. 10 is a three-dimensional view of another PCB and a slot according to a third embodiment of the present invention.

FIG. 11 is a schematic diagram illustrating a first state of a bridge device according to a fourth embodiment of the present invention.

FIG. 12 is a schematic diagram illustrating a second state of a bridge device according to a fourth embodiment of the present invention.

### DESCRIPTION OF EMBODIMENTS

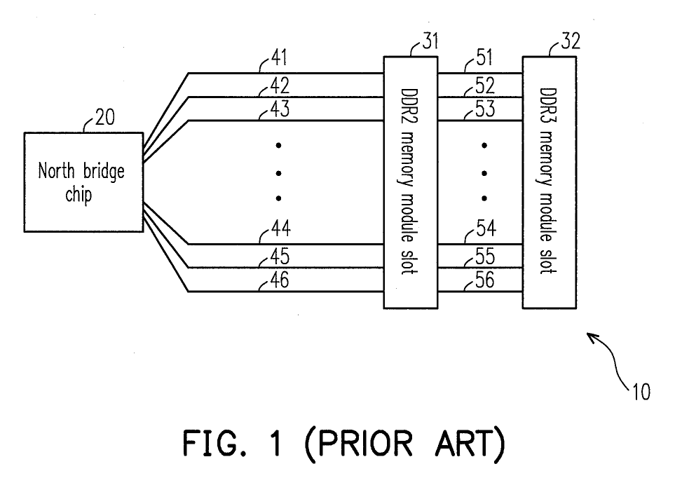

By studying the embodiment of FIG. 1 in detail, some disadvantages thereof are further disclosed. First, when the north bridge chip 20 outputs a signal to the DDR2 memory module slot 31 via the conducting wires 41-46, the signal can be shunted to the DDR3 memory module slot 32 along the conducting wires 51-56, so that an intensity of the signal received by the DDR2 memory module slot 31 is weakened. Second, when the signal is transmitted from the DDR2 memory module slot 31 to the DDR3 memory module slot 32, an echo signal is derived at the DDR3 memory module slot 32 and is transmitted back to the DDR2 memory module slot 31. The echo signal can be regarded as a noise. Therefore, quality of the signal received by the DDR2 memory module slot 31 is decreased. Third, lengths of the conducting wires 41-46 are different, so that signal synchronization cannot be ensured, which may lead to a system failure, or even boot failure.

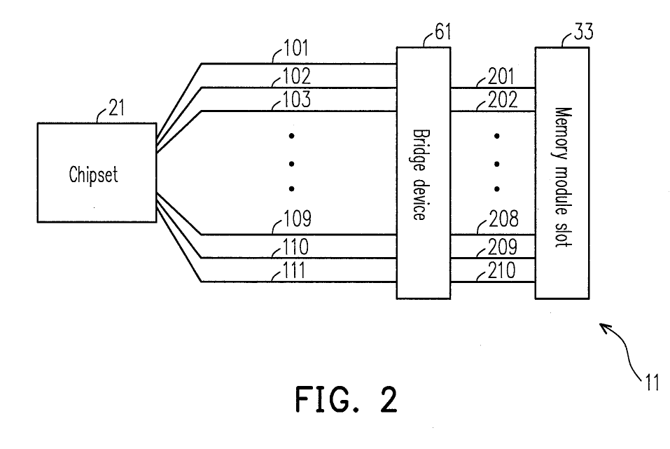

FIG. 2 is a schematic diagram illustrating a motherboard according to a first embodiment of the present invention. Referring to FIG. 2, in the present embodiment, the motherboard 11 includes a chipset 21, a memory module slot 33, a bridge device 61, a plurality of first conducting wires and a plurality of second conducting wires, wherein the first conducting wires are, for example, conducting wires 101-111, and the second conducting wires are, for example, 201-210. In the present embodiment, the chipset 21 may include a north bridge chip. The conducting wires 101-111 can be coupled between the north bridge chip of the chipset 21 and the bridge device 61. The conducting wires 201-210 can be coupled between the memory module slot 33 and the bridge device 61.

The chipset 21 and the memory module slot 33 can support more than two standards of memory module. In the present embodiment, the chipset 21 and the memory module slot 33 can support a DDR2 standard memory module and a DDR3 standard memory module. Generally, a number of pins of the DDR2 memory module is the same to that of the DDR3 memory module. The memory module slot 33 generally has a proof thinking device to prevent inserting of an incompatible memory module. However, in the present embodiment, to insert the memory modules of different standards into the memory module slot 33, the proof thinking device of the memory module slot 33 is removed. Therefore, the memory module slot 33 can be used for accommodating the memory modules of different standards, for example, the DDR2 or the DDR3 standard memory module.

In the present embodiment, the conducting wires 102-111 can correspondingly connect the chipset 21 to the DDR2 memory module of the memory module slot 33. The conducting wires 101-110 can correspondingly connect the chipset 21 to the DDR3 memory module of the memory module slot 33. It should be noted that the bridge device 61 can be used for determining a coupling relation between the conducting wires 101-111 and the conducting wires 201-210, so as to enable the chipset 21 to support the memory modules of different standards. An embodiment of the bridge device 61 is further described below.

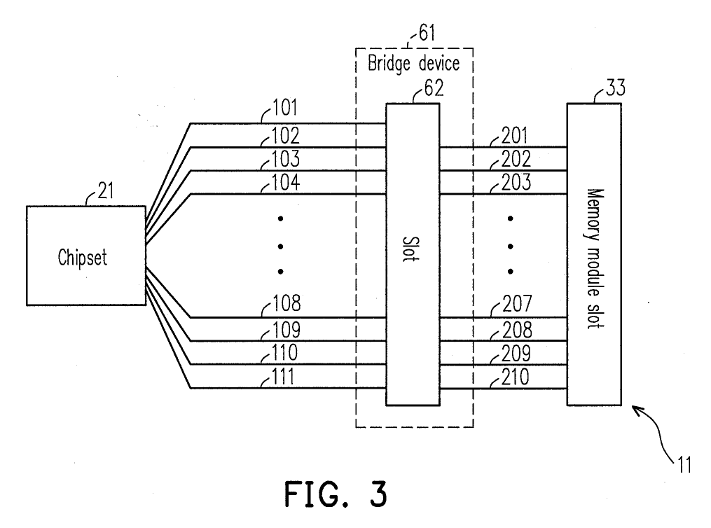

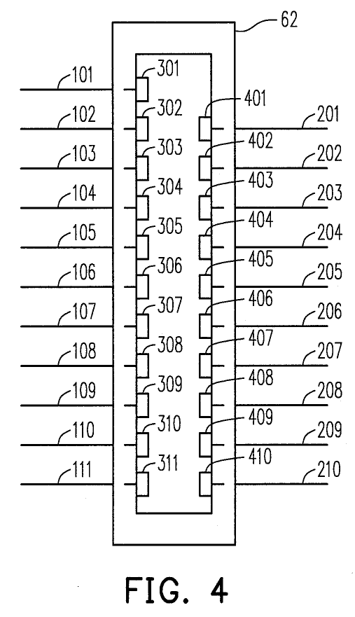

FIG. 3 is a schematic diagram illustrating a bridge device according to the first embodiment of the present invention. FIG. 4 is a top view of a slot according to the first embodiment of the present invention. Referring to FIG. 3 and FIG. 4, in the present embodiment, the bridge device 61 may include a slot 62. The slot 62 includes metal pads 301-311, 401-410. The metal pads 301-311 are respectively coupled to the conducting wires 101-111. The metal pads 401-410 are respectively coupled to the conducting wires 201-210. The slot 62 can be used for accommodating different printed circuit boards (PCB), so as to determine different coupling relations between the metal pads 301-311 and the metal pads 401-410.

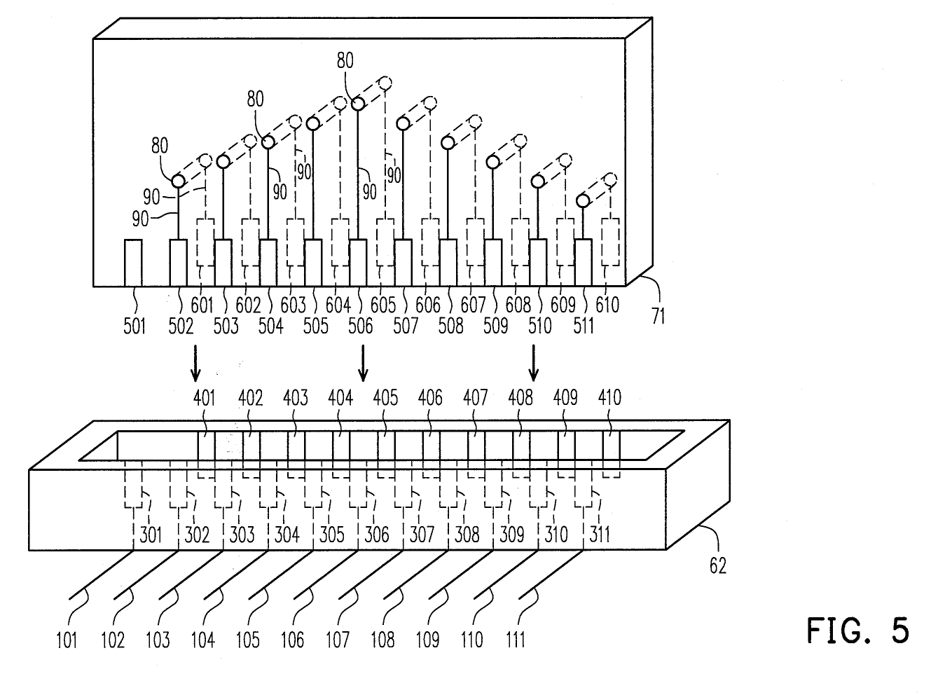

For example, FIG. 5 is a three-dimensional view of a PCB and a slot according to the first embodiment of the present invention. Referring to FIGS. 3-5, the PCB 71 includes metal pads 501-511, 601-610, a plurality of conductive via 80 and a plurality of wires 90. In the PCB 71, the metal pads 502 and 601 are electrically connected through the wire 90 and the conductive via 80. Deduced by analogy, the metal pads 503-511 are electrically connected to the metal pads 602-610 through the wires 90 and the conductive via 80, respectively.

Accordingly, when the PCB 71 is inserted to the slot 62, the metal pads 501-511 are respectively contacted to the metal pads 301-311, and the metal pads 601-610 are respectively contacted to the metal pads 401-410, so that the metal pads 302-311 are electrically connected to the metal pads 401-410, respectively. Namely, the conducting wires 102-111 are electrically connected to the conducting wires 201-210, respectively. By such means, the chipset 21 can support the DDR2 memory module inserted in the memory module slot 33.

It should be noted that in the present embodiment, the PCB 71 provides an adequate wiring space. Therefore, those skilled in the art can adjust the lengths of the conducting wires based on the wiring space of the PCB 71, so as to match the lengths of the conducting wires between the chipset 21 and the DDR2 memory module inserted in the memory module slot 33. For example, the length of the conducting wire 103 of FIG. 3 is greater than the length of the conducting wire 104, so that in the PCB 71, the length of the wire 90 between the metal pads 504 and 603 (corresponding to the conducting wire 104) can be designed to be greater than the wire 90 between the metal pads 503 and 602. (corresponding to the conducting wire 103). Similarly, length match of other conducting wires can be deduced by analogy, and detailed description thereof is not repeated. By such means, asynchronization of the signals caused by mismatching of the lengths of the conducting wires in the conventional technique can be mitigated.

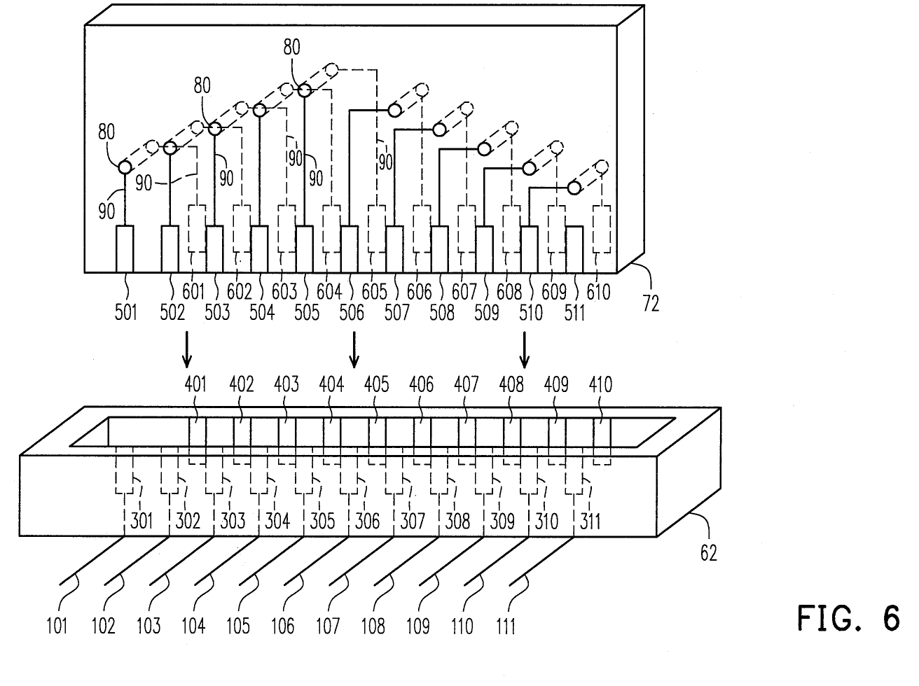

Moreover, FIG. 6 is three-dimensional view of another PCB and a slot according to the first embodiment of the present invention. Referring to FIGS. 3, 4 and 6, the PCB 72 includes metal pads 501-511, metal pads 601-610, a plurality of conductive via 80 and a plurality of wires 90. In the PCB 72, the metal pads 501 and 601 are electrically connected through the wire 90 and the conductive via 80. Deduced by analogy, the metal pads 502-510 are electrically connected to the metal pads 602-610 through the wires 90 and the conductive via 80, respectively.

Accordingly, when the PCB 72 is inserted to the slot 62, the metal pads 501-511 are respectively contacted to the metal pads 301-311, and the metal pads 601-610 are respectively contacted to the metal pads 401-410, so that the metal pads 301-310 are electrically connected to the metal pads 401-410, respectively. Namely, the conducting wires 101-110 are electrically connected to the conducting wires 201-210, respectively. By such means, the chipset 21 can support the DDR3 memory module inserted in the memory module slot 33.

In the present embodiment, the PCB 72 also provides an adequate wiring space. Therefore, those skilled in the art can adjust the lengths of the conducting wires based on the wiring space of the PCB 72, so as to match the lengths of the conducting wires between the chipset 21 and the DDR3 memory module inserted in the memory module slot 33. By such means, asynchronization of the signals caused by mismatching of the lengths of the conducting wires in the conventional technique can be mitigated.

In summary, the memory module slot 33 and the chipset 21 can support the memory modules with different specifications. Moreover, the coupling relation between the conducting wires 101-111 and the conducting wires 201-210 can be varied by applying the bridge device 61, so that the memory modules with different specifications inserted in the memory module slot 33 can all be electrically connected to the chipset 21. Moreover, the bridge device 61 can provide an adequate wiring space, so that asynchronization of the signals caused by mismatching of the lengths of the conducting wires in the conventional technique can be mitigated. In the following content, the present embodiment is further compared to the conventional technique, so as to highlight the advantages of the present embodiment.

Referring to FIG. 1 and FIG. 3, in the conventional technique, when the DDR2 standard memory module is inserted in the DDR2 memory module slot 31, the DDR3 memory module slot 32 is in the idle state, which may lead to a waste of the cost. Though, the memory module slot 33 of the present embodiment does not have the above problem.

In the conventional technique, when the north bridge chip 20 outputs a signal to the DDR2 memory module slot 31 via the conducting wires 41-46, the signal can be shunted to the DDR3 memory module slot 32 along the conducting wires 51-56, so that an intensity of the signal received by the DDR2 memory module slot 31 is weakened. Though, the memory module slot 33 of the present embodiment does not have the above problem.

In the conventional technique, when the signal is transmitted from the DDR2 memory module slot 31 to the DDR3 memory module slot 32, an echo signal is derived at the DDR3 memory module slot 32, so that quality of the signal received by the DDR2 memory module slot 31 is decreased. Though, the memory module slot 33 of the present embodiment does not have the above problem.

Though a possible pattern of the motherboard is illustrated according to the above embodiment, those skilled in the art should understand that different manufactures have different designs for the motherboard, so that application of the present invention is not limited to such possible pattern. In other words, the present invention includes following features. A plurality of the first conducting wires is coupled between the chipset and the bridge device. Moreover, a plurality of second conducting wires is coupled between the memory module slot and the bridge device. When the bridge device provides a N^{th} route set, the motherboard supports a N^{th} standard memory module inserted in the memory module slot. The N^{th} route set is electrical connected between a N^{th} wire group of the first conducting wires and a N^{th} wire group of the second conducting wires, wherein N is a natural number. As long as the above features are matched, it is construed to be within the scope of the present invention. In the following content, more embodiments are provided to fully convey the spirit of the present invention to those skilled in the art.

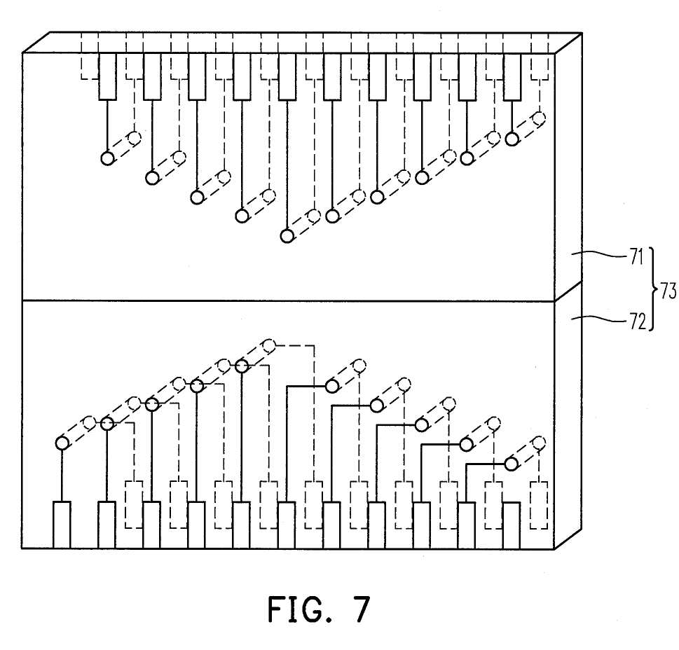

Referring to FIG. 5 and FIG. 6 again, in the aforementioned embodiment, the PCBs 71 and 72 are taken as an example, thought the present invention is not limited thereto, and in other embodiment, those skilled in the art can change the wiring or the pattern of the PCB. For example, FIG. 7 is a schematic diagram illustrating a PCB according to a second embodiment of the present invention. Referring to FIGS. 3 and 5-7, wherein descriptions of the elements with the same reference numerals with that of the above embodiment are not repeated. It should be noted that the PCB 73 may include PCBs 71 and 72. To be specific, an upper part of the PCB 73 is the PCB 71, and a lower part of the PCB 73 is the PCB 72.

Namely, when the DDR2 memory module is inserted in the memory module slot 33, the slot 62 can be inserted to the upper part of the PCB 73, so that motherboard 11 can support the DDR2 memory module. When the DDR3 memory module is inserted in the memory module slot 33, the slot 62 can be inserted to the lower part of the PCB 73, so that motherboard 11 can support the DDR3 memory module. An advantage of such method is that when the PCB 71 is utilized, the PCB 72 is guaranteed to be not lost. Similarly, when the PCB 72 is utilized, the PCB 71 is also guaranteed to be not lost.

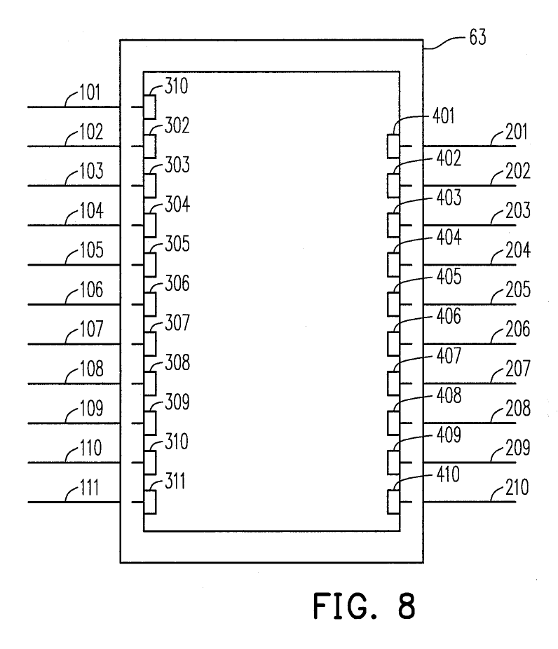

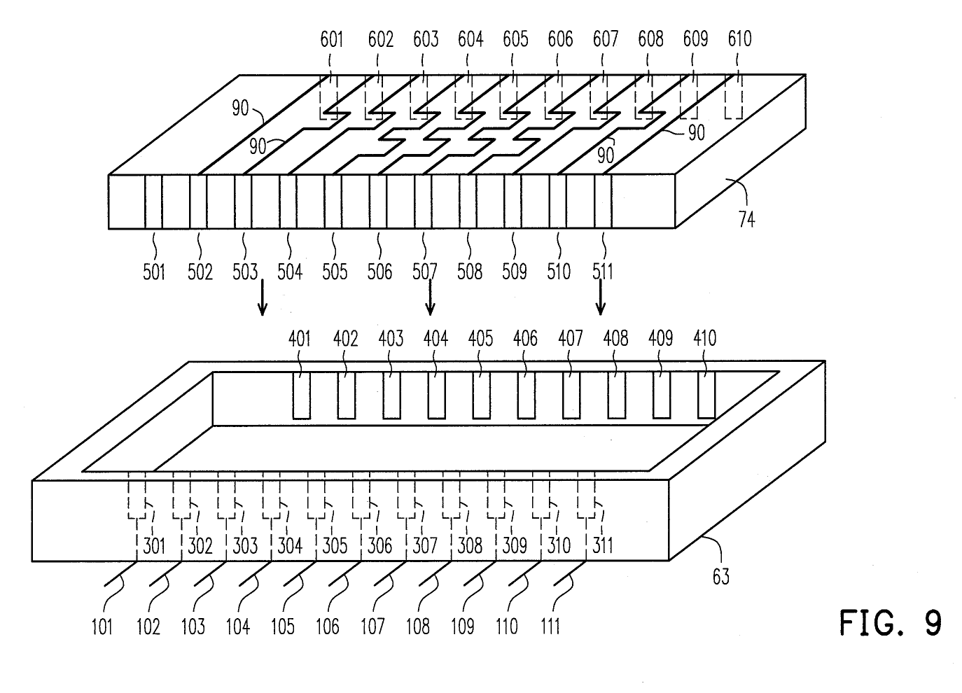

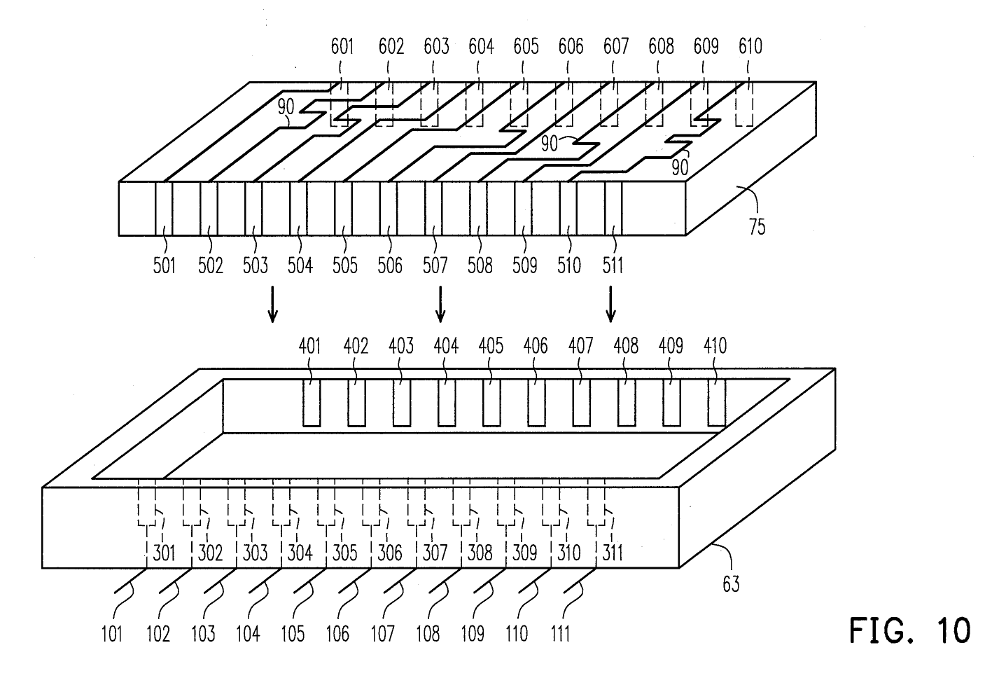

Referring to FIG. 4-FIG. 6 again, in the aforementioned embodiment, though the slot 62 is taken as an example, the present invention is not limited thereto, and in other embodiments, those skilled in the art can change a structure or a pattern of the slot, and accordingly change the pattern of the PCB. For example, FIG. 8 is a top view of a slot according to a third embodiment of the present invention. FIG. 9 is a three-dimensional view of a PCB and a slot according to the third embodiment of the present invention. FIG. 10 is a three-dimensional view of another PCB and a slot according to the third embodiment of the present invention. Referring to FIGS. 4-6 and FIGS. 8-10, wherein descriptions of the elements with the same reference numerals with that of the above embodiment are not repeated. It should be noted that the slot 62 of the aforementioned embodiment is substituted by a slot 63 of the present embodiment, and the PCBs 71 and 72 of the aforementioned embodiment are substituted by PCBs 74 and 75 of the present embodiment. By such means, functions similar to that of the aforementioned embodiment can also be achieved.

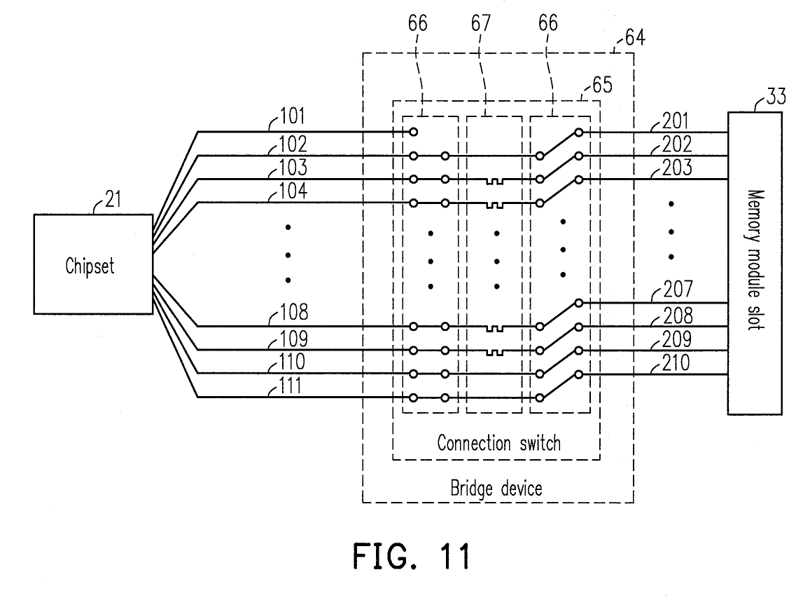

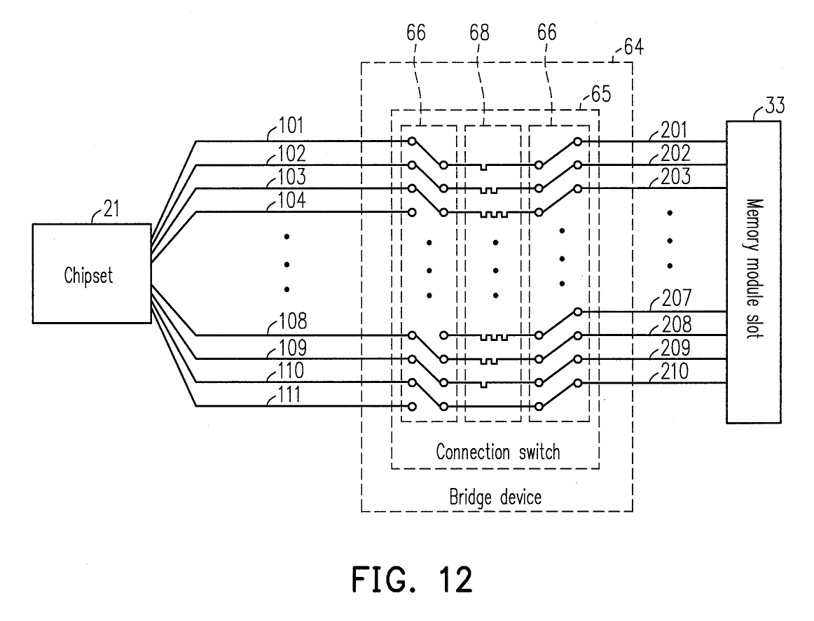

Referring to FIG. 3 again, in the aforementioned embodiment, though the bridge device 61 is taken as an example, the present invention is not limited thereto, and in other embodiments, those skilled in the art can change a pattern of the bridge device. For example, FIG. 11 is a schematic diagram illustrating a first state of a bridge device according to a fourth embodiment of the present invention. FIG. 12 is a schematic diagram illustrating a second state of a bridge device according to a fourth embodiment of the present invention. Referring to FIG. 3 and FIGS. 11 and 12, wherein descriptions of the elements with the same reference numerals with that of the above embodiment are not repeated. It should be noted that the bridge device 61 of the aforementioned embodiment is substituted by a bridge device 64 of the present embodiment.

In the present embodiment, the bridge device 64 includes a connection switch 65. The connection switch is connected between the conducting wires 101-111 and the conducting wires 201-210. The connection switch 65 includes switch units 66 and route sets 67 and 68. In the present embodiment, the bridge device 64 can detect a standard of the memory module inserted in the memory module slot 33, so as to determine the coupling relation between the conducting wires 101-111 and the conducting wires 201-210.

When the DDR2 memory module is inserted in the memory module slot 33, the switch units 66 are switched to a first state, and the route set 67 is electrically connected between the conducting wires 102-111 and the conducting wires 201-210. By such means, the chipset 21 can support the DDR2 memory module inserted in the memory module slot 33. Since the route set 67 provides an adequate wiring space, by adjusting the lengths of the conducting wires, asynchronization of the signals caused by mismatching of the lengths of the conducting wires in the conventional technique can be mitigated.

When the DDR3 memory module is inserted in the memory module slot 33, the switch units 66 are switched to a second state, and the route set 68 is electrically connected between the conducting wires 101-110 and the conducting wires 201-210. By such means, the chipset 21 can support the DDR3 memory module inserted in the memory module slot 33. Since the route set 68 also provides an adequate wiring space, by adjusting the lengths of the conducting wires, asynchronization of the signals caused by mismatching of the lengths of the conducting wires in the conventional technique can be mitigated.

In the present embodiment, thought the connection switch 65 is taken as an example, the present invention is not limited thereto, and in other embodiment of the present invention, those skilled in the art can also design different numbers of the route set applied in the connection switch 65 according to actual requirements, so that the motherboard can support the memory module with more standards.

In summary, in the motherboard of the present invention, a plurality of the first conducting wires is coupled between the chipset and the bridge device, and a plurality of the second conducting wires is coupled between the memory module slot and the bridge device. When the bridge device provides a N^{th} route set, the motherboard supports a N^{th} standard memory module inserted in the memory module slot. The N^{th} route set is electrical connected between a N^{th} wire group of the first conducting wires and a N^{th} wire group of the second conducting wires. By such means, not only the motherboard can support the memory modules of different standards, but also the signal transmission quality is improved. Moreover, embodiments of the present invention have at least the following advantages:

1. The bridge device can provide an adequate wiring space, so that asynchronization of the signals caused by mismatching of the lengths of the conducting wires in the conventional technique can be mitigated.

2. The memory module slot of the conventional technique can only accommodate a single standard memory module, while the memory module slot of the embodiments of the present invention can accommodate the memory modules of different standards.

3. In the conventional technique, a plurality of different standard memory module slots are configured to the motherboard, though the different standard memory modules cannot be simultaneously utilized, which may lead to a waste of the cost. Comparatively, the memory module slots of the embodiments of the present invention can be fully utilized, and a forcibly idle problem can be avoided.

4. In the embodiments of the present invention, interference of the echo signal can be mitigated, and the signal quality can be improved.

5. In the embodiments of the present invention, reduction of the signal intensity due to shunting of the signal can be avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A motherboard, comprising:
a chipset;
a memory module slot;
a bridge device;
a plurality of first conducting wires, coupled between the chipset and the bridge device; and
a plurality of second conducting wires, coupled between the memory module slot and the bridge device,
wherein when the bridge device provides a first route set, the motherboard supports a first standard memory module inserted in the memory module slot, wherein the first route set is electrical connected between a first wire group of the first conducting wires and a first wire group of the second conducting wires, and
when the bridge device provides a second route set, the motherboard supports a second standard memory module inserted in the memory module slot, wherein the second route set is electrical connected between a second wire group of the first conducting wires and a second wire group of the second conducting wires.

2. The motherboard as claimed in claim 1, wherein the bridge device comprises:
a slot, coupled to the first conducting wires and the second conducting wires, for accommodating a wiring board, the wiring board having a first route set, a second route set or a combination thereof.

3. The motherboard as claimed in claim 2, wherein the wiring board is a printed circuit board (PCB).

4. The motherboard as claimed in claim 1, wherein the bridge device comprises:
a connection switch, coupled to the first conducting wires and the second conducting wires, and having the first route set and the second route set,
wherein when the connection switch is switched to a first state, the first route set is electrical connected between the first wire group of the first conducting wires and the first wire group of the second conducting wires, and
when the connection switch is switched to a second state, the second route set is electrical connected between the second wire group of the first conducting wires and the second wire group of the second conducting wires.

5. The motherboard as claimed in claim 1, wherein the chipset comprises a north bridge chip.

6. The motherboard as claimed in claim 1, wherein the first standard memory module is a DDR2 memory module.

7. The motherboard as claimed in claim 1, wherein the second standard memory module is a DDR3 memory module.
